(19) United States
(12) Patent Application Publication
(10) Pub. No.: US 2012/0008264 A1
(43) Pub. Date: Jan. 12, 2012

(54) PROTECTION AND POSITIONING DEVICE FOR REMOTE USER INTERFACE

(75) Inventors: Thomas Don Lahti, Appleton, WI (US); Jeffery Ray Ihde, Greenville, WI (US)

(73) Assignee: Illinois Tool Works Inc., Glenview, IL (US)

(21) Appl. No.: 13/174,369

(22) Filed: Jun. 30, 2011

Related U.S. Application Data
(60) Provisional application No. 61/363,061, filed on Jul. 9, 2010.

(51) Int. Cl. H05K 7/00

(52) U.S. Cl. 361/679.01

(57) ABSTRACT

An external positioning structure for a remote user interface is provided. The external positioning structure includes a roll cage assembly configured to receive at least a portion of the remote user interface and at least partially surround lateral sides of the remote user interface. The roll cage assembly further includes a plurality of fastening points allowing for securement of the roll cage assembly to the remote user interface.

### CROSS REFERENCE TO RELATED APPLICATIONS

This application is a Non-Provisional patent application of U.S. Provisional Patent Application No. 61/363,061 entitled “Rollcage Hanging Device”, filed Jul. 9, 2010, which is herein incorporated by reference.

### BACKGROUND

The invention relates generally to welding systems, and, more particularly, to a protection and positioning device for a remote user interface of a welding system.

Welding systems generally include power supplies configured to provide an electric current for use in a welding operation. The power supplies include a user interface allowing an operator to adjust one or more operating parameters of the power supply. For example, the user interface may enable are the operator to select or adjust voltage output, current output, welding wire size, welding process, and so forth. For certain welding applications, the power supplies, which may weigh over 80 pounds, are too large or cumbersome to position proximate to the welding operation. For example, the location of a weld may be elevated, confined, restricted, or otherwise difficult to access. In such circumstances, a remote user interface may be connected to the power supply, enabling an operator to adjust power supply operating parameters without being proximate to the power supply. For example, the remote user interface may include a remote pendant that is coupled to the power supply by a long cable. Unfortunately, remote user interfaces are frequently used in harsh environments where they may be subjected to dropping, dragging, falling debris, and other general abuse.

### BRIEF DESCRIPTION

In an exemplary embodiment, an external positioning structure for a remote user interface includes a roll cage assembly configured to receive at least a portion of a remote user interface and at least partially surround lateral sides of the remote user interface and a plurality of fastening points on the roll cage assembly, the fastening points allowing for securement of the roll cage assembly about the remote user interface.

In another exemplary embodiment, an external positioning structure for a remote user interface includes a roll cage assembly having a first roll cage member couple to a second roll cage member by a cross brace, the roll cage assembly configured to receive at least a portion of a remote user interface at and least partially surround lateral sides of the remote user interface. The external position structure also includes a plurality of fastening points on the roll cage assembly, the fastening points allowing for adjustment and securement of the roll cage assembly about the remote user interface.

In a further embodiment, an external positioning structure for a remote user interface includes a first roll cage member, a second roll cage member identical to the first roll cage member, and a cross brace coupled to the first roll cage member and the second roll cage member, the first and second roll cage members and the cross brace configured to receive at least a portion of a remote user interface and at least partially surround lateral sides of the remote user interface. The external positioning structure also includes a plurality of fastening points on the first and second roll cage members, the fastening points allowing for adjustment and securement of the first and second roll cage members and the cross brace about the remote user interface.

### DRAWINGS

These and other features, aspects, and advantages of the present invention will become better understood when the following detailed description is read with reference to the accompanying drawings in which like characters represent like parts throughout the drawings, wherein:

FIG. 1 is a diagrammatical representation of an exemplary welding system;

FIG. 2 is a perspective view of two exemplary external positioning structures disposed about a remote user interface for a welding power supply;

FIG. 3 is a perspective view of an exemplary external position structure for use with a remote user interface of a welding power supply;

FIG. 4 is a perspective view of an exemplary external position structure for use with a remote user interface of a welding power supply;

FIG. 5 is a perspective view of two exemplary external positioning structures disposed about a remote user interface for a welding power supply, illustrating an exemplary positioning configuration of the external positioning structures; and

FIG. 6 is a perspective view of two exemplary external positioning structures disposed about a remote user interface for a welding power supply, illustrating an exemplary positioning configuration of the external positioning structures.

### DETAILED DESCRIPTION

The present disclosure describes exemplary embodiments of an external positioning structure for use with a remote user interface of a welding power supply. The external positioning structure is configured allow the remote user interface to be positioned in several different orientations, such as various forms of hanging and resting on flat surfaces. Additionally, the external positioning structure is configured to protect the remote user interface from general abuse, such as dropping, dragging, falling debris, and the like. In certain embodiments, the external positioning structure includes two claw members coupled by a cross brace member. The claw members are configured to protect the remote user interface from harmful contact with a surface (e.g., when the remote user interface is dropped or dragged). The claw members also enable versatile positioning of the remote user interface, such as hanging the remote user interface from a bar or rail. Furthermore, the external positioning structure is coupled to the remote user interface with fasteners. The fasteners may be configured to allow rotation and fixation of the external positioning structure about the remote user interface in various positions, thereby providing versatile positioning capability of the remote user interface. As discussed below, in certain applications, more than one external positioning structure may be coupled to the remote user interface.

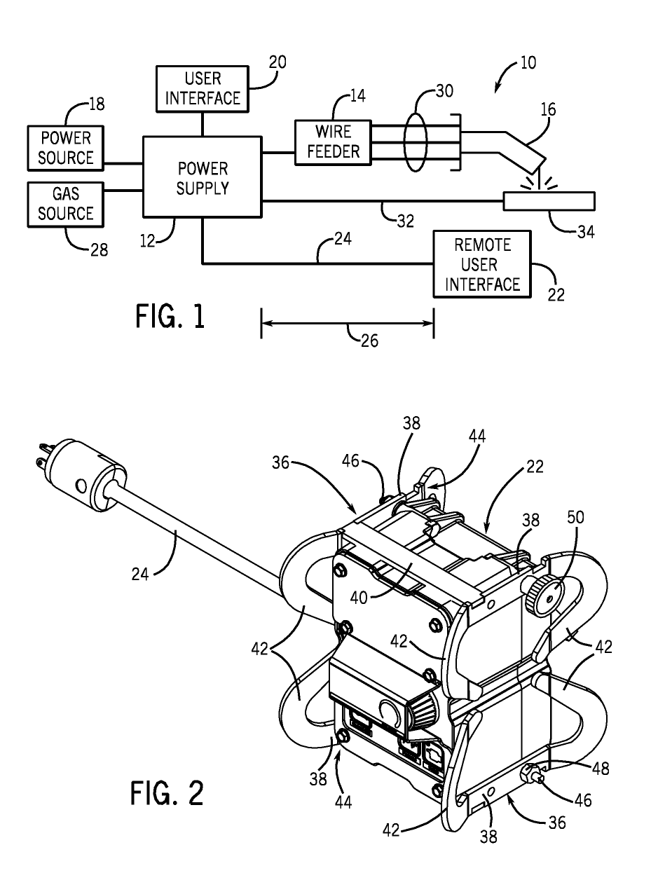

Turning now to the drawings, FIG. 1 illustrates an exemplary welding system 10 which powers, controls, and provides supplies to a welding operation. The welding system 10 includes a welding power supply 12, a wire feeder 14, and a welding torch 16. The power supply 12 may be a power converter style welding power supply or an inverter welding power supply requiring a power source 18. In other embodiments, the welding power supply 12 may include a generator or alternator driven by an internal combustion engine. The welding power supply 12 may also include a user interface 20 for inputting or adjusting various operating parameters of the welding power supply 12, such as voltage and current. In some embodiments, the user interface 20 may further be configured to input or adjust various operating parameters of the welding wire feeder 14, such as welding wire diameter, wire feed speed, and so forth.

Additionally, a remote user interface 22 is coupled to the welding power supply 12. The remote user interface 22 may be used in applications where the welding power supply 12 is too large or cumbersome to position proximate to the welding application. For example, the remote user interface 22 may be used in welding environments such as power plants where the location of a weld is elevated or difficult to access. An extension cord 24, which may be a 115 volt cable, intelligent serial cable, or other extension cord, connects the remote user interface 22 to the welding power supply 12. As shown, the remote user interface 22 is positioned proximate to the welding torch 16 (i.e., the welding application), at a distance 26 from the welding power supply 12. In certain applications, the distance 26 may be approximately 50 feet, 100 feet, 150 feet, or more. As with the user interface 20, the remote user interface 22 is configured to input or adjust various operating parameters of the welding power supply 12, such as voltage and current, and the welding wire feeder 14, such as welding wire diameter and wire feed speed. As discussed in detail below, the remote user interface 22 may include an external positioning structure configured to protect the remote user interface 22 and allow the remote user interface 22 to be positioned in several different orientations.

A gas source 28 may also be coupled to the welding power supply 12. The gas source 28 is the source of the gas that is supplied to the welding torch 16. As shown, the welding power supply 12 is coupled to the welding wire feeder 14. As will be appreciated, the welding power supply 12 may be coupled to the welding wire feeder 14 by a feeder power lead, a weld cable, a gas hose, and a control cable. The welding wire feeder 14 in the illustrated embodiment provides welding wire to the welding torch 16 for use in the welding operation. Specifically, the welding wire feeder 14 feeds welding wire from a spool to the welding torch 16. A variety of welding wires may be used. For example, the welding wire may be solid (e.g., carbon steel, aluminum, stainless steel), composite, flux cored, and so forth. Furthermore, the thickness of the welding wire may vary depending on the welding application for which the welding wire is used. For example, the welding wire may be 22 gauge, 20 gauge, 18 gauge, 16 gauge, or other size. The welding wire feeder 14 may enclose a variety of internal components such as a wire feed drive system, an electric motor assembly, an electric motor, and so forth.

As shown, the welding wire supplied by the welding wire feeder 14 is fed to the welding torch 16 through a first cable 30. The first cable 30 may also supply gas to the welding torch 16. As further shown, a second cable 32 couples the welding power supply 12 to a work piece 34 (typically via a clamp) to complete the circuit between the welding power supply 12 and the welding torch 16 during a welding operation.

It should be noted that modifications to the exemplary welding system 10 of FIG. 1 may be made in accordance with aspects of the present invention. For example, the welding wire feeder 14 may further include a user interface to enable a user to input and adjust various wire feed settings or operating parameters of the welding wire feeder 14, such as wire feed speed, welding wire diameter, and so forth. Furthermore, although the illustrated embodiments are described in the context of a metal inert gas (MIG) welding process, the features of the invention may be utilized with a variety of welding processes.

FIG. 2 is a perspective view of the remote user interface 22 with two external positioning structures 36 coupled to the remote user interface 22. In other embodiments, the remote user interface 22 may include a single external positioning structure 36. The structures 36 are configured to protect the remote user interface 22 in the event that the remote user interface 22 is dropped or dragged across a surface. More specifically, the structures 36 extend outward from the remote user interface 22 in multiple directions, such that the structures 36, rather than the remote user interface 22, will contact a surface on which the remote user interface 22 is dropped or dragged. The structures 36 are further configured to allow the remote user interface 22 to be positioned in several different orientations.

Each external positioning structure 36 includes claw members 38 and a cross brace 40 coupled to the claw members 38. Specifically, the claw members 38 and the cross brace 40 form a box-like configuration that is disposed about the remote user interface 22. When the structure 36 is disposed about the remote user interface 22, the claw members 38 and cross brace 40 each abut a different surface of the remote user interface 22. Each claw member 38 further includes hook portions 42 that extend outward from the remote user interface 22. If the remote user interface 22 is dropped or dragged, the hook portions 42 of the claw members 38, rather than the remote user interface 22, may contact the surface on which the remote user interface 22 is dropped or dragged, thereby preventing possible damage to the remote user interface 22.

Furthermore, the hook portions 42 of the claw members 38 may be used to hang the remote user interface 22 on a bar or rail proximate to the welding application. As discussed below, each external positioning structure 36 may be rotated about the remote user interface 22 and securely positioned such that one or more hook portions 42 may grab or be affixed to a bar or rail. Similarly, each structure 36 may be positioned to provide a variety of different orientations (e.g., viewing angles) of the remote user interface 22 on a flat surface. As indicated by reference numeral 44, the claw members 38 of the structures 36 extend beyond the surface of the remote user interface 22. Consequently, when the remote user interface 22 is positioned on a flat surface, the claw members 38 and the cross brace 40 of the structure 36 may contact the flat surface with the remote user interface 22 is suspended slightly above the flat surface. In this manner, the remote user interface 22 may be tilted (i.e., rotated about the structure 36 resting on the flat surface) to provide a desired orientation or viewing angle.

In the illustrated embodiment, each external positioning structure 36 is secured to the remote user interface 22 with bolts 46, a nut 48, and a threaded knob 50. In certain embodiments, the bolts 46 are built into the remote user interface 22. The threaded knob 50, which is engaged with one of the bolts 46, allows the structure 36 to be rotated and fixated about the remote user interface 22 in a variety of orientations. Specifically, the threaded knob 50 may be loosened, the structure 36 may be rotated about the remote user interface 22 to a desired position, and the threaded knob 50 may be tightened to secure structure 36 to the remote user interface 22 in the desired position. As discussed above, the positioning flexibility of the structure 36 about the remote user interface 22 enables the remote user interface 22 to be rested on a surface or hung on a rail in different positions (e.g., viewing angles).

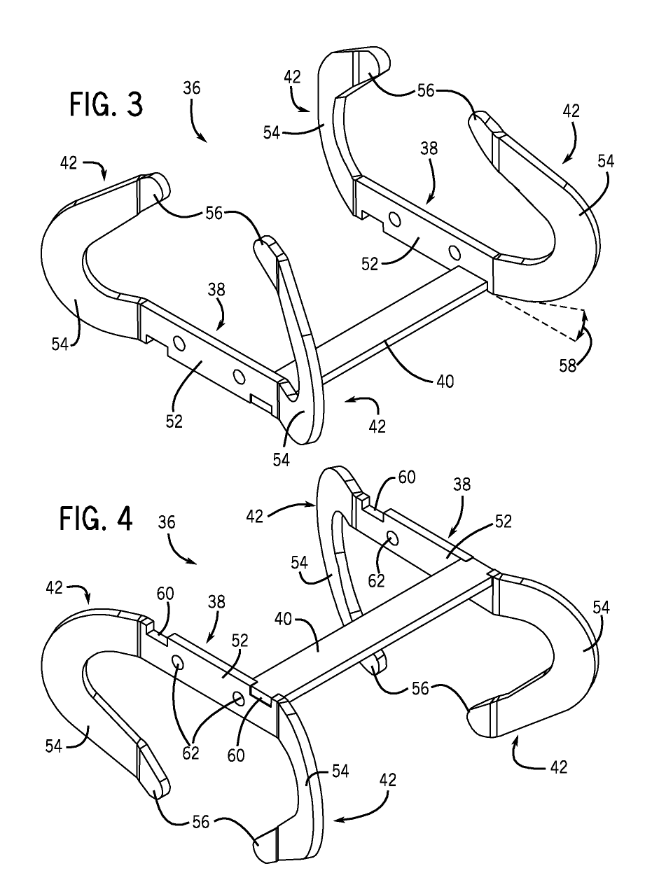

FIG. 3 is a perspective view of the external positioning structure 36, illustrating an angled configuration of the hook portions 42 of the claw members 38. As discussed above, the structure 36 includes two claw members 38 coupled by a cross brace 40. As shown, both claw members 38 of the structure 36 are identical. As a result, a single configuration of the claw member 38 may be manufactured, and the claw member 38 can be used for either side of the structure 36. In other embodiments, each claw member 38 of the structure 36 may have a unique configuration.

Each claw member 38 includes a base portion 52 from which the hook portions 42 extend. In the illustrated embodiment, the hook portions 42 of each claw member 38 extend from opposite ends of the base portion 52. As will be appreciated, the claw members 38 may have a single piece construction from a material such as steel or plastic. For example, the claw members 38 may be formed from a machining process such as punching or laser cutting. As mentioned above, the hook portions 42 have an angled configuration. More specifically, each hook portion 42 includes an elbow 54 and a tip 56. The elbow 54 of each hook portion 42 is oriented at an angle 58 relative to the base portion 52 and the tip 56. In certain embodiments, the angle 58 may measure approximately 10 degrees, 20 degrees, 30 degrees, 40 degrees, or more. In this manner, the structure 36 may provide protection for the remote user interface 22 from multiple directions. The angled orientation of the elbow 54 may be created using a press break or other machining tool. Furthermore, while the elbows 54 for all hook portions 42 of the structure 36 are angled in the illustrated embodiment, other embodiments may include elbows 54 which are angled and elbows 54 which are not angled.

FIG. 4 is a perspective view of the external positioning structure 36, illustrating the coupling of the cross brace 40 to the claw members 38. Each end of the cross brace 40, which may be formed from a metal, such as steel, or a plastic, is disposed in a notch 60 formed in the base portion 52 of the each claw member 38. The cross brace 40 may be secured to the notches 60 of base portions 52 by a welding, brazing, or other fusing process. As shown, notches 60 are formed at both ends of the base portion 52 of each claw member 38, allowing for alternate configurations of the structure 36. For example, in embodiments of the remote user interface 22 having two structures 36, the structures 36 may have different configurations. In other words, one structure 36 may have the cross brace 40 coupled to the base portions 52 at one end, and another structure 36 may have the cross brace 40 coupled to the base portions 52 at another end. In other embodiments, the base portion 52 of each claw member 38 may include a single notch 60 or more than two notches 60 to allow for additional configurations of the structure 36.

The base portions 52 of the claw members 38 also include holes 62. As will be appreciated, the holes 62 in the base portions are configured to receive the bolts 46 of the remote user interface 22. That is, the structure 36 is mounted to the remote user interface 22 by inserting the bolts 46 through the holes 62 and securing the structure 36 to the remote user interface 22 by tightening the nut 48 or threaded knob 50 on each bolt 46. As similarly described above, holes 62 are formed on both ends of the base portion 52 of each claw member 38, allowing alternative mounting configurations of the structure 36 to the remote user interface 22. For example, in embodiments of the remote user interface 22 having two structures 36, the structures 36 may be mounted to the remote user interface 22 using holes 62 at different respective locations on the base portion 52 of each claw member 38. Furthermore, while the illustrated embodiment shows two holes 62 formed in each base portion 52, other embodiments of the structure 36 may have a single hole 62 or more than two holes 62 formed in the base portion 52 of each claw member 38.

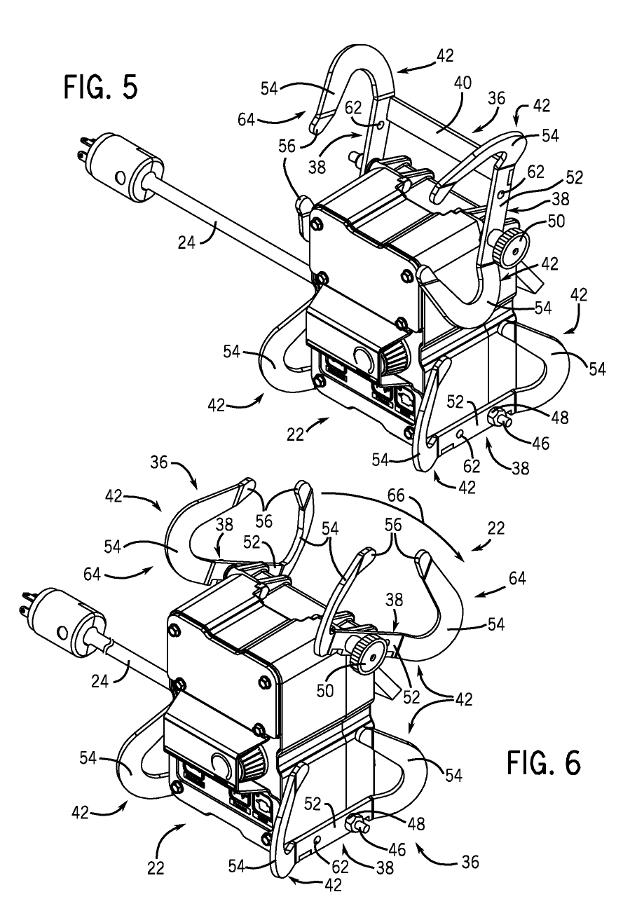

FIGS. 5 and 6 are perspective views of the remote user interface 22, each having two external positioning structures 36, illustrating various positioning configurations of the external positioning structures 36 about the remote user interface 22. As discussed above, the position or orientation of the structures 36 about the remote user interface 22 may be adjusted by loosening the threaded knob 50 of the structure 36 to be adjusted, adjusting the structure 36 to a desired position, and subsequently tightening the threaded knob 50. For example, FIG. 5 shows the remote user interface 22 having a top external positioning structure 64 oriented such that hook portions 42 of the top external positioning structure 64 may receive a bar or rail proximate to the welding application. In this manner, the remote user interface 22 may hang on the bar or rail while on operator completes a welding operation. For example, the bar or rail may be a handrail or a rung of a ladder. Additionally, should an operator wish to adjust or input an operating parameter of the welding power supply 12 or the welding wire feeder 14, the operator may do so using the remote user interface 22, without needing to move or reposition the remote user interface 22. In other words, the remote user interface 22 may hang on the bar or rail and remain stationary while the operator completes the welding operation. Furthermore, as the hook portions 42 of the top structure 64 are engaged with the bar or rail (i.e., the hook portions 42 are substantially wrapped around the bar or rail), the risk of dislodging or knocking the remote user interface 22 off the bar or rail is reduced.

FIG. 6 illustrates an alternative orientation of the top external positioning structure 64 coupled to the remote user interface 22. The orientation of the top structure 64 in the illustrated embodiment may be configured to receive a bar or rail, such that the remote user interface 22 may be positioned proximate to a welding application. Alternatively, the remote user interface 22 may be rotated in a direction 66 and rested on a flat surface. Specifically, in the resting position, the remote user interface 22 is supported by the elbows 54 of the structures 36. In this manner, an alternative viewing angle of the remote user interface 22 may be provided.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An external positioning structure for a remote user interface, comprising:
a roll cage assembly configured to receive at least a portion of a remote user interface and at least partially surround lateral sides of the remote user interface; and
a plurality of fastening points on the roll cage assembly, the fastening points allowing for securement of the roll cage assembly about the remote user interface.

2. The structure of claim 1, wherein the roll cage assembly comprises a first roll cage member coupled to a second roll cage member by a cross brace.

3. The structure of claim 2, wherein the cross brace is coupled to the first roll cage member and the second roll cage member by welding or brazing.

4. The structure of claim 2, wherein the first roll cage member and the second roll cage member have identical constructions.

5. The structure of claim 2, wherein the fastening points comprise apertures formed the first and second roll cage members, the apertures configured to receive fasteners of the remote user interface.

6. The structure of claim 2, wherein the first and second roll cage members each comprises two or more fastening points allowing for multiple mounting configurations of the roll cage assembly to the remote user interface.

7. The structure of claim 2, wherein the first and second roll cage members each comprise hook portions, the hook portions extending outward from the remote user interface and configured to engage a bar to facilitate hanging of the remote user interface.

8. The structure of claim 7, wherein at least one hook portion is configured to form an acute angle with at least one lateral side of the remote user interface when the roll cage assembly is secured to the remote user interface.

9. The structure of claim 1, wherein the fastening points are configured to enable rotation of the roll cage assembly about the remote user interface.

10. The structure of claim 1, wherein the roll cage assembly is formed from a metal or plastic.

11. An external positioning structure for a remote user interface, comprising:
a roll cage assembly having a first roll cage member coupled to a second roll cage member by a cross brace, the roll cage assembly configured to receive at least a portion of a remote user interface and at least partially surround lateral sides of the remote user interface; and
a plurality of fastening points on the roll cage assembly, the fastening points allowing for adjustment and securement of the roll cage assembly about the remote user interface.

12. The structure of claim 11, wherein the first and second roll cage members each comprise hook portions configured to engage with a bar or rail.

13. The structure of claim 12, wherein each hook portion forms an acute angle with at least one surface of the remote user interface.

14. The structure of claim 11, wherein adjustment of the roll cage assembly about the remote user interface comprises loosening at least one fastening point, rotating the roll cage assembly about the remote user interface to a desired position, and tightening the at least one fastening point.

15. The structure of claim 11, wherein then plurality of fastening points are apertures formed in the first and second roll cage members, and the fastening points are configured to receive posts of the remote user interface.

16. The structure of claim 11, wherein the first and second roll cage members have an identical construction.

17. The structure of claim 11, wherein the first and second roll cage members and the cross brace are formed from metal, plastic, or a combination thereof.

18. An external positioning structure for a remote user interface, comprising:
a first roll cage member;
a second roll cage member identical to the first roll cage member;
a cross brace coupled to the first roll cage member and the second roll cage member, the first and second roll cage members and the cross brace configured to receive at least a portion of a remote user interface and at least partially surround lateral sides of the remote user interface;
a plurality of fastening points on the first and second roll cage members, the fastening points allowing for adjustment and securement of the first and second roll cage members and the cross brace about the remote user interface.

19. The structure of claim 18, wherein the first and second roll cage members are coupled to the cross brace by welding or brazing.

20. The structure of claim 18, wherein the first and second roll cage members each comprise hook portions configured to extend outward from the remote user interface at an acute angle and engage with a bar or rail.
